(19) United States
(12) Patent Application Publication
(10) Pub. No.: US 2010/0140700 A1
(43) Pub. Date: Jun. 10, 2010

(54) SEMICONDUCTOR DEVICE AND METHOD FOR MANUFACTURING THE SAME

(76) Inventor: Sang-Yong Lee, Bucheon-si (KR)

Correspondence Address: SHERR & VAUGHN, PLLC, 620 HERNDON PARKWAY, SUITE 320, HERNDON, VA, 20170, US

(21) Appl. No.: 12/624,765

(22) Filed: Nov. 24, 2009

(30) Foreign Application Priority Data
Dec. 4, 2008 (KR) 10-2008-0122790

(51) Int. Cl. H01L 29/78; H01L 21/22; H01L 29/772

(52) U.S. Cl. 257/343; 438/514; 257/327; 438/142; 257/E21.135; 257/E29.261

(57) ABSTRACT

A semiconductor device and a method of manufacturing a semiconductor device. A semiconductor device may include a substrate and a laterally diffused metal oxide semiconductor (LDMOS) device. A semiconductor device may include a second conductive type well formed on and/or over a substrate. An LDMOS device may include a drain disposed on and/or over a substrate. An LDMOS device may include a field oxide at one side of a drain, a first conductive type impurity layer on and/or over a substrate, under a field oxide, and/or a second conductive type impurity layer between a first conductive type impurity layer and a field oxide.

The present application claims priority under 35 U.S.C. 119 to Korean Patent Application No. 10-2008-0122790 (filed on Dec. 4, 2008) which is hereby incorporated by reference in its entirety.

### BACKGROUND

Embodiments relate to a semiconductor device and a method of manufacturing a semiconductor device.

A metal oxide semiconductor field effect transistor (MOSFET) may have a relatively high input impedance compared to a bipolar transistor, such that a power gain may be maximized and/or a gate driving circuit may be relatively simple. A MOSFET may be a unipolar device, and/or there may be substantially no time delay caused by accumulation and/or recombination of minority carriers while turned-off. Therefore, a MOSFET may be increasingly applied to a variety of fields, such as a switching mode power supply, a lamp ballast and/or a motor driving circuit.

For a power MOSFET, a double diffused MOSFET (DMOSFET) structure which may use a planar diffusion technology may be widely used, which may be represented by a laterally diffused metal oxide semiconductor (LDMOS) transistor. Accordingly, there is a need for a semiconductor device and a method of manufacturing a semiconductor device which may maximize withstanding-voltage of a device and/or minimize on-resistance.

### SUMMARY

Embodiments relate to a semiconductor device and a method of manufacturing a semiconductor device. According to embodiments, a semiconductor device and a method of manufacturing a semiconductor device may maximize withstanding-voltage of a device, for example by maximizing a breakdown voltage of a laterally diffused metal oxide semiconductor (LDMOS) device. In embodiments, a semiconductor device and a method of manufacturing a semiconductor device may minimize on-resistance, for example by shortening a current flow distance.

Embodiments relate to a semiconductor device. According to embodiments, a semiconductor device may include a substrate on and/or over which a second conductive type well may be formed. In embodiments, a semiconductor device may include an LDMOS device, which may include a drain disposed on and/or over a substrate. In embodiments, an LDMOS device may include a field oxide at one side of a drain, a first conductive type impurity layer on and/or over a substrate under a field oxide and/or a second conductive type impurity layer between a first conductive type impurity layer and a field oxide.

Embodiments relate to a semiconductor device. According to embodiments, a semiconductor device may include a substrate on and/or over which a second type well may be formed. In embodiments, a semiconductor device may include a gate electrode on and/or over a substrate. In embodiments, a semiconductor device may include a first conductive type body at one side of a gate electrode and/or a source region on and/or over a first conductive type body. In embodiments, a semiconductor device may include a drain region at an opposite side of a gate electrode. In embodiments, a semiconductor device may include a field oxide between a source region and a drain region. In embodiments, a semiconductor device may include a first conductive type top region on and/or over a second conductive type well under a field oxide. In embodiments, a semiconductor device may include a second conductive type top region on and/or over a second conductive type well between a field oxide and a first conductive type top region.

Embodiments relate to a method of manufacturing a semiconductor device. According to embodiments, a semiconductor device may include a field oxide on and/or a gate electrode. In embodiments, a method of manufacturing a semiconductor device may include forming a second conductive type well on and/or over a first conductive type substrate. In embodiments, a method of manufacturing a semiconductor device may include forming a first conductive type top region and/or a second conductive type top region by implanting first conductive type impurities and/or second conductive type impurities on and/or over a second conductive type well under a region where a field oxide may be formed. In embodiments, a method of manufacturing a semiconductor device may include forming a first conductive type body and/or a field oxide on and/or over a second conductive type well.

### DRAWINGS

FIG. 1 is a view illustrating a semiconductor device in accordance with embodiments.

FIG. 2 is a view illustrating characteristics of a laterally diffused metal oxide semiconductor (LDMOS) in accordance with embodiments.

FIG. 3 to FIG. 6 are views illustrating a method of manufacturing an LDMOS in accordance with embodiments.

FIG. 7 is a view illustrating a semiconductor device in accordance with embodiments.

FIG. 8 is a view illustrating a semiconductor device in accordance with embodiments.

FIG. 9 is a view illustrating a semiconductor device in accordance with embodiments.

### DESCRIPTION

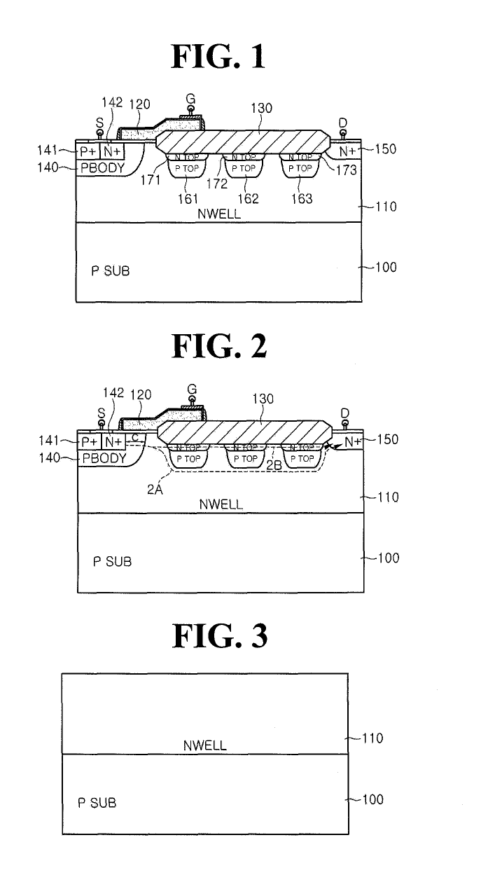

Embodiments relate to a semiconductor device. Referring to example FIG. 1, a view illustrates a semiconductor device in accordance with embodiments, which may include a cross-sectional view illustrating a configuration of a laterally diffused metal oxide semiconductor (LDMOS) device. Referring to example FIG. 2, a cross-sectional view illustrates characteristics of a LDMOS device in accordance with embodiments.

Referring to FIG. 1 and FIG. 2, an LDMOS device may include a second conductive type high-concentration N-type buried layer on and/or over a first conductive type P-type semiconductor substrate, and/or a P-type epitaxial layer on and/or over a buried layer. According to embodiments, a voltage may be applied to N+ type drain region 150 and/or an N-type buried layer may substantially increase a punch through voltage, for example by minimizing a width of a depletion region extended from P-type body 140. In embodiments, a gas-state semiconductor crystal may be extracted on and/or over a monocrystalline wafer which may serve as a substrate, and/or a crystal may be grown along a crystal axis of a P-type substrate. In embodiments, a P-type epitaxial layer may minimize resistibility of a P-type substrate.

According to embodiments, N-type deep well 110 may be formed on and/or over semiconductor substrate 100. In embodiments, a channel region may be formed adjacent to a surface of P-type body 140, for example between a contact surface of P-type body 140, N-type deep well 110 and/or N+ type source region 142, according to a bias voltage applied to gate electrode 120. In embodiments, a gate electrode may include a gate oxide formed at a certain position on and/or over semiconductor substrate 100. In embodiments, a portion of a gate electrode 120 may be formed on and/or over field oxide 130. In embodiments, spacers may be formed at opposing sidewalls of gate electrode 120.

According to embodiments, P-type body 140 may be formed at one side of gate electrode 120 on and/or over semiconductor substrate 100. In embodiments, N+ type source region 142 and/or P+ type contact region 141 may be formed on and/or over P-type body 140. In embodiments, P-type body 140 may include a relatively high concentration, which may maximize a punch through phenomenon of an LDMOS. In embodiments, field oxide 130 and/or the N+ type drain region 150 may be formed at an opposite side of gate electrode 120 on and/or over semiconductor substrate 100.

According to embodiments, a plurality of impurity regions may be formed under field oxide 130, which may maximize withstanding-voltage and/or minimize on-resistance from a viewpoint of Safe Operation Area (SOA). In embodiments, N-type top regions 171, 172 and/or 173 may be formed under field oxide 130, which may minimize on-resistance of a device for example by providing another path of a current by a channel formed on and/or over P-type body. In embodiments, P-type top regions 161, 162 and/or 163 may maximize pressure-resistance of a device under the N-type top regions 171, 172 and/or 173. In embodiments, P-type top regions 161, 162 and/or 163 may maximize withstanding-voltage under field oxide 130, such that it may be unnecessary to increase the size of field oxide 130 to address withstanding-voltage.

According to embodiments, a current flow path of a LDMOS device may include a first path formed according to P-type top regions 161, 162 and/or 163. In embodiments, a current flowing path of a LDMOS device may include a second path flowing through N-type top regions. In embodiments, a first path may be formed under a P-type top region.

According to embodiments, N-type top regions 171, 172 and/or 173 may be impurity layers implanted with second conductive type impurities between field oxide 130 and P-type top regions 161, 162 and/or 163. In embodiments, N-type top regions 171, 172 and/or 173 may provide a second path for a current flowing through a channel formed on and/or over a P-type body, for example in addition to a first path formed under P-type top regions 161, 162 and/or 163. In embodiments, impurity layers between field oxide 130 and P-type top regions 161, 162 and/or 163 may be implanted with second conductive type N-type impurities of substantially the same conductive type as a drain region.

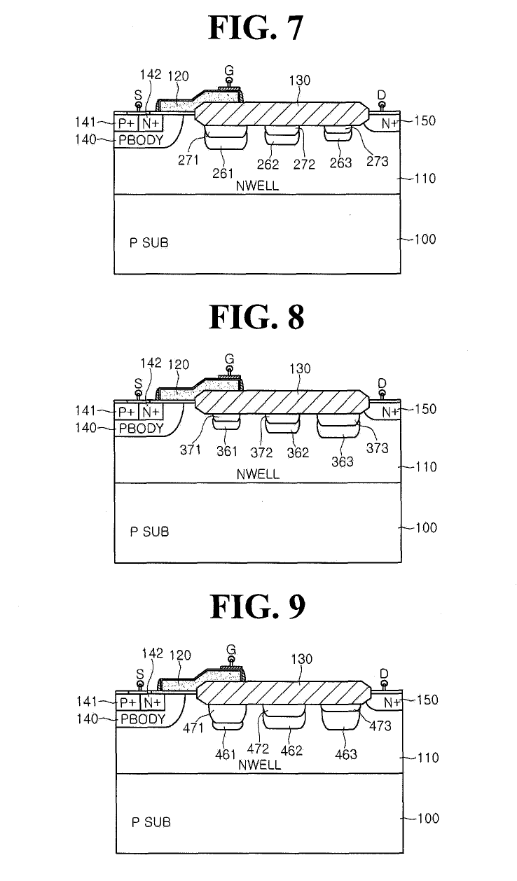

According to embodiments, P-type top regions 161, 162 and/or 163 may have substantially the same size as each other. In embodiments, N-type top regions 171, 172 and/or 173 may have substantially the same size as each other. In embodiments, P-type and N-type top regions may have different sizes from each other, for example as illustrated in example FIG. 7 to FIG. 9. Referring to FIG. 7, an LDMOS device is illustrated in accordance with embodiments. In embodiments, P-type top regions 261, 262 and/or 263, and/or N-type top regions 271, 272 and/or 273 may decrease in size as the distance from a P-type body progressively increases.

Referring to FIG. 8, an LDMOS device is illustrated in accordance with embodiments. In embodiments, P-type top regions 361, 362 and/or 363, and/or N-type top regions 371, 372 and/or 373 may increase in size as the distance from a P-type body progressively increases. Referring to FIG. 9, an LDMOS device is illustrated in accordance with embodiments. In embodiments, P-type top regions 461, 462 and/or 463 may increase in size as the distance from a P-type body progressively increases, and/or N-type top region 471, 472 and/or 473 may increase in size as the distance from the P-type body progressively increases. In embodiments, N-type regions 471, 472 and/or 473 may decrease in size as the distance from a P-type body progressively increases. In embodiments, P-type top regions and/or N-type top regions may be formed in different sizes, for example according to their positions.

Referring to FIG. 2, with respect to operation of an LDMOS device in accordance with embodiments, electrons may move through a channel C which may be formed on and/or over P-type body 140. In embodiments, with respect to a current flow, first path 2A may pass under P-type top regions 161, 162 and/or 163, and/or second path 2B may be formed between field oxide 130 and P-type top regions 161, 162 and/or 163. In embodiments, P-type top regions 161, 162 and/or 163 may form a junction region on and/or over N-type deep well 110, thereby minimizing a drift region and/or equalizing capacitances of parasitic capacitors between drain region 150 and source region 142.

According to embodiments, P-type top regions 161, 162 and/or 163 may be positioned on and/or over an expanded drain region of N-type deep well 110, and/or may generate an electromagnetic field on and/or over N-type deep well 110 to maximize a breakdown voltage. In embodiments, a maximized withstanding-voltage by P-type top regions 161, 162 and/or 163 may be achieved and/or a filed oxide may be formed having a relatively smaller size. In embodiments, a current flowing path may be formed under P-type top regions 161, 162 and/or 163, and/or on-resistance characteristics may be minimized. In embodiments, another current flowing path may be provided between field oxide 130 and P-type top regions 161, 162 and/or 163.

Embodiments relate to a method of manufacturing an LDMOS device. Referring to example FIG. 3 to FIG. 6, views illustrate a method of manufacturing an LDMOS device in accordance with embodiments. Referring to FIG. 3, a second conductive type, for example N-type, ions may be implanted on and/or over a first conductive type semiconductor substrate 100 to form N-type deep well 110. According to embodiments, for example prior to forming N-type deep well 110, an N+ type buried layer may be formed on and/or over semiconductor substrate 100, and N-type impurities may be implanted to form N-type deep well 110.

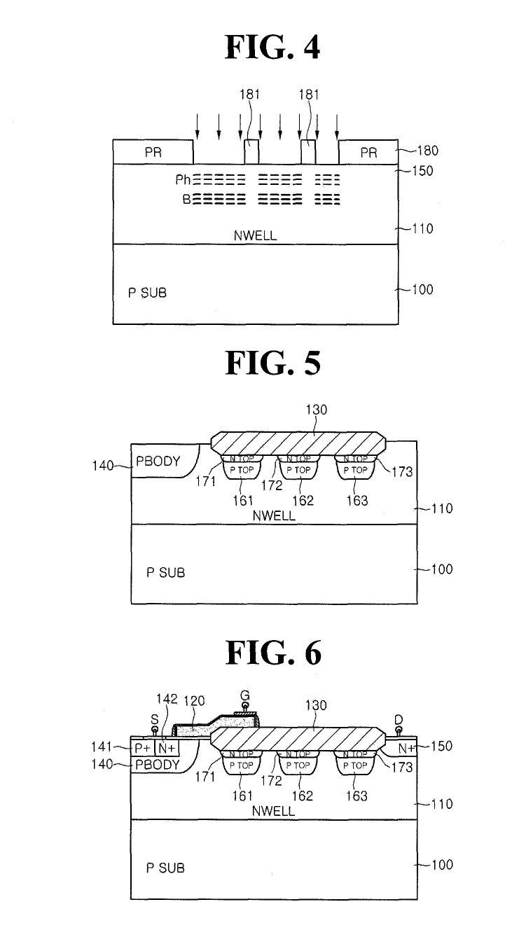

Referring to FIG. 4, processes may be performed to form a N-type top region implanted with second conductive type ions, and/or a P-type top region implanted with first conductive type ions on and/or over semiconductor substrate 100. According to embodiments, an impurity implantation processes to form a N-type top region and/or a P-type top region may include forming photoresist pattern 180, opening a predetermined impurity implantation region on and/or over substrate 100. In embodiments, photoresist pattern 180 may be coated on and/or over a region excluding a region where field oxide may be formed. In embodiments, an impurity implantation process may include a pattern 181 to form a plurality of N-type top regions and/or P-type top regions.

According to embodiments, second conductive type impurities and/or first conductive type impurities may be sequentially implanted using patterned photoresist pattern 180 as an ion implantation mask. In embodiments, an implantation depth may differ according to differences of implantation energies for ion implantations. In embodiments, second conductive type impurities to form a N-type top region may include phosphorus (P), and/or first conductive type impurities to form P-type top region may include boron (B). In embodiments, for example after an impurity implantation process to form N-type and/or P-type top regions on and/or over N-type deep well 110, photoresist pattern 180 may be removed.

Referring to FIG. 5, a photoresist pattern may be coated on and/or over a predetermined region to form P-type body 140. In embodiments, an ion implantation process may be performed using a photoresist as an ion implantation mask to form P-type body 140. In embodiments, for example after a pad oxide and/or a nitride may be deposited on and/or over a substrate, a nitride may be patterned in an active region of a device. In embodiments, a thermal oxidation process may be performed on and/or over a nitride to form field oxide 130. In embodiments, in a thermal oxidation process to form field oxide 130, a heat-treatment may be performed on and/or over N-type top regions 171, 172 and/or 173, and/or P-type top regions 161, 162 and/or 163 to form N-type top regions and/or P-type top regions.

Referring to FIG. 6, an impurity implantation processes may be performed to form P+ type contact region 141, N+ type source region 142 and/or N+ type drain region 150. In embodiments, a gate oxide may be formed on and/or over a region where gate electrode 120 may be formed. In embodiments, gate electrode 120 may be formed on and/or over a gate oxide.

According to embodiments, a LDMOS device may be formed. In embodiments, withstanding-voltage of an LDMOS device may be maximized, for example by maximizing a breakdown voltage of an LDMOS device. In embodiments, resistance of a drift region may be minimized, for example by forming an additional current flowing path which may shorten a current flowing distance.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. An apparatus comprising:
a second conductive type well over a substrate; and
a laterally diffused metal oxide semiconductor device comprising a drain over said substrate, a field oxide at one side of the drain, a first conductive type impurity layer over the substrate and under the drain, and a second conductive type impurity layer between said first conductive type impurity layer and said field oxide.

2. The apparatus of claim 1, wherein said first conductive type impurity layer and said second conductive type impurity layer comprise a plurality of first and second conductive type impurity layers.

3. The apparatus of claim 2, wherein said plurality of first and second conductive type impurity layers are disposed at a predetermined interval.

4. The apparatus of claim 2, comprising a first conductive P-type body at one side of said field oxide, wherein at least one of said plurality of first conductive type impurity layers and said plurality of second conductive type impurity layers decrease in size as a distance from said P-type body increases.

5. The apparatus of claim 2, comprising a first conductive P-type body at one side of said field oxide, wherein at least one of said plurality of first conductive type impurity layers and said plurality of second conductive type impurity layers increase in size as a distance from said P-type body increases.

6. The apparatus of claim 2, comprising a first conductive P-type body at one side of said field oxide, wherein the size of at least one of said plurality of first conductive type impurity layers and said plurality of said second conductive type impurity layers remains substantially constant as a distance from said P-type body increases.

7. An apparatus comprising:
a second conductive type well over a substrate;
a gate electrode over the substrate;
a first conductive type body comprising a source region at one side of said gate electrode;
a drain region at an opposite side of said gate electrode;
a field oxide between said source region and said drain region;
a first conductive type top region over said second conductive type well under said field oxide; and
a second conductive type top region between said field oxide and said first conductive type top region.

8. The apparatus of claim 7, wherein said first conductive type top region and said second conductive type top region comprise a plurality of first and second conductive type top regions.

9. The apparatus of claim 8, wherein said plurality of first conductive type top regions comprise different sizes at a predetermined interval.

10. The apparatus of claim 9, wherein said plurality of first conductive type top regions decrease in size as a distance from said first conductive type body increases.

11. The apparatus of claim 9, wherein said plurality of first conductive type top regions increase in size as a distance from said first conductive type body increases.

12. The apparatus of claim 8, wherein said plurality of first conductive type top regions are substantially the same size at a predetermined interval.

13. The apparatus of claim 8, wherein said plurality of second conductive type top regions comprise different sizes at a predetermined interval.

14. The apparatus of claim 13, wherein said plurality of second conductive type top regions decrease in size as a distance from said first conductive type body increases.

15. The apparatus of claim 13, wherein said second conductive type top regions increase in size as a distance from said first conductive type body increases.

16. The apparatus of claim 7, wherein said first conductive type comprises a P-type and said second conductive type comprises an N-type.

17. A method comprising:
forming a second conductive type well over a substrate;
forming at least one of a first conductive type top region and a second conductive type top region by implanting at least one of first conductive type impurities and second conductive type impurities over said second conductive type well under a region where a field oxide is to be formed; and
forming at least one of a first conductive type body and a field oxide over said second conductive type well.

18. The method of 17, wherein forming said at least one first conductive type top region and second conductive type top region comprises:
coating a photoresist pattern to open a region where said field oxide is to be formed; and
performing a plurality of ion implantation processes using said photoresist pattern as an ion implantation mask.

19. The method of claim 18, wherein said photoresist pattern comprises a pattern configured to allow said first conductive type top region and said second conductive type top region to be separately formed in plurality.

20. The method of claim 17, wherein said second conductive top region is formed between said first conductive type top region and said field oxide.
